(19) United States
(12) Patent Application Publication
(10) Pub. No.: US 2026/0209106 A1
(43) Pub. Date: Jul. 23, 2026

(54) ALKALI-FREE GLASS PLATE

(71) Applicant: Nippon Electric Glass Co., Ltd., Shiga (JP)

(72) Inventor: Mayu NISHIMIYA, Shiga (JP)

(21) Appl. No.: 19/140,648

(22) PCT Filed: Dec. 14, 2023
(86) PCT No.: PCT/JP2023/044916

§ 371 Date: Jun. 18, 2025

(30) Foreign Application Priority Data
Dec. 26, 2022 (JP) 2022-207730
Jun. 1, 2023 (JP) 2023-090624

(51) Int. Cl. C03C 3/087; C03C 3/091

(52) U.S. Cl. CPC C03C 3/087; C03C 3/091

(57) ABSTRACT

The present invention provides an alkali-free glass sheet, including as a glass composition, in terms of mol %, 65% to 72% of SiO₂, 11% to 15% of Al₂O₃, 2% to 5% of B₂O₃, 0% to 0.5% of Li₂O+Na₂O+K₂O, 2% to 8% of MgO, 4% to 10% of CaO, 0% to 4% of SrO, 0% to 4% of BaO, and 11% to 17% of MgO+CaO+SrO+BaO, and having a mole percent ratio (MgO+CaO+SrO+BaO−Al₂O₃)/B₂O₃ of from 0.2 to 1, a mole percent ratio SrO/CaO of from 0 to 0.6, a mole percent ratio BaO/CaO of from 0 to 0.6, and a value determined from the formula 0.116×[Al₂O₃]−0.079×[B₂O₃]+0.155×[MgO]+0.299×[CaO]+0.336×[SrO]+0.385×[BaO] of from 2% to 8%.

### TECHNICAL FIELD

The present invention relates to an alkali-free glass sheet, and more specifically, to an alkali-free glass sheet suitable for an OLED display and an information recoding medium.

### BACKGROUND ART

An electronic device such as an OLED display is used in applications, such as a flexible device and a display of a cellular phone, because the electronic device is thin, is excellent in displaying a video, and has low power consumption.

A glass sheet is widely used as a substrate for the OLED display. The glass sheet for this application is mainly required to satisfy the following characteristics.
(1) To be substantially free of an alkali metal oxide, that is, to be alkali-free glass (glass having a content of an alkali metal oxide of 0.5 mol % or less in its glass composition) in order to prevent a situation in which an alkali ion is diffused into a semiconductor substance formed into a film in a heat treatment step.
(2) To be formed by an overflow down-draw method, by which an improvement in surface quality is easily achieved, and to be excellent in productivity, particularly excellent in meltability and devitrification resistance in order to achieve a reduction in cost of the glass sheet.
(3) To have a high strain point in order to reduce the thermal shrinkage of the glass sheet in a low temperature polysilicon (LTPS) process or an oxide TFT process.

In addition, an information recording medium, such as a magnetic disk or an optical disc, is used in various information instruments.

A glass sheet is widely used as a substrate for an information recording medium in place of a related-art aluminum alloy substrate. In recent years, in order to meet a need for a further increase in recording density, a magnetic recording medium using an energy-assisted magnetic recording system, that is, an energy-assisted magnetic recording medium has been investigated. The glass sheet is used also in the energy-assisted magnetic recording medium, and a magnetic layer or the like is formed on a surface of the glass sheet. In the energy-assisted magnetic recording medium, an ordered alloy having a large magnetic anisotropy coefficient Ku (hereinafter referred to as “high Ku”) is used as a magnetic material for the magnetic layer.

### CITATION LIST

Patent Literature 1: JP 2012-106919 A
Patent Literature 2: JP 2021-086643 A
Patent Literature 3: JP 3804111 B2

### SUMMARY OF INVENTION

### Technical Problem

Incidentally, an OLED device has been widely deployed also in an OLED TV. There are strong demands for an increase in size and a reduction in thickness of the OLED TV, and there is an increasing demand for a display having a high resolution of 8K or the like. Accordingly, a glass sheet for those applications is required to have such thermal dimensional stability as to be able to withstand the high resolution demand while achieving an increase in size and a reduction in thickness. Further, for the OLED TV, in order to reduce a difference in price from a liquid crystal display, a reduction in cost is required, and the glass sheet is similarly required to be reduced in cost. However, when the glass sheet is increased in size and reduced in thickness, the glass sheet is liable to be deflected, resulting in a rise in manufacturing cost.

The glass sheet formed by a glass manufacturer is subjected to, for example, cutting, annealing, testing, and washing steps, and during these steps, the glass sheet is loaded into a cassette in which a plurality of shelves are formed and is discharged therefrom. The cassette is generally configured so that two sides of the glass sheet facing each other are placed on shelves formed on left and right inner surfaces of the cassette to allow the glass sheet to be held in a horizontal direction. A large and thin glass sheet has a large deflection amount, and hence at the time of the loading of the glass sheet into the cassette, part of the glass sheet is brought into contact with the cassette, and the glass sheet is liable to be broken. At the time of the discharge, the glass sheet largely swings and is liable to be unstable. The cassette having such configuration is also used in an electronic device manufacturer, resulting in occurrence of similar defects. In order to solve the above-mentioned problems, a method involving increasing the Young's modulus of the glass sheet to reduce the deflection amount thereof is effective.

In addition, as described above, it is required that the strain point of the glass sheet be increased in order to reduce the thermal shrinkage of a large glass sheet in the LTPS process or the oxide TFT process for obtaining a display having a high resolution.

However, when the Young's modulus and strain point of the glass sheet are to be increased, the glass composition loses its balance, with the result that productivity is reduced, and particularly the devitrification resistance is remarkably reduced, and the glass sheet cannot be formed by an overflow down-draw method owing to an increase in liquidus viscosity. In addition, the meltability is reduced or a glass forming temperature is increased, with the result that the lifetime of a forming trough is liable to be shortened. As a result, the raw sheet cost of the glass sheet rises.

Further, when the Young's modulus and strain point of the glass sheet are to be increased, durability to buffered hydrofluoric acid (BHF) containing, for example, hydrofluoric acid and ammonium fluoride as main components to be used for etching of SiOx or SiNx is reduced. As a result, there may occur a problem in that glass is liable to be etched, and hence cloudiness occurs in the LTPS process or the oxide TFT process.

In addition, a glass sheet for a magnetic recording medium is required to have high rigidity (Young's modulus) so as not to cause large deformation at the time of high-speed rotation. Specifically, in a disc-shaped magnetic recording medium, while a medium is subjected to high-speed rotation around a center axis, and while a magnetic head is moved in a radial direction, writing and reading of information are performed along a rotation direction. In recent years, a rotation number for increasing the speed of the writing or the speed of the reading has been advancing in the direction of higher speeds from 5,400 rpm to 7,200 rpm, and further to 10,000 rpm. In addition, in the disc-shaped magnetic recording medium, a position for recording information is assigned in accordance with a distance from the center axis in advance. Accordingly, when the glass sheet causes deformation during the rotation, a positional shift of the magnetic head occurs, and accurate reading becomes difficult.

In addition, in recent years, large narrowing (reduction in flying height) of a gap between a recording/reproducing element portion of the magnetic head and a surface of the magnetic recording medium has been achieved to achieve a further increase in recording density by mounting a dynamic flying height (DFH) mechanism on the magnetic head. The DFH mechanism is a mechanism in which a heating unit such as an extremely small heater is arranged in the vicinity of the recording/reproducing element portion of the magnetic head to thermally expand only around the element portion toward a medium surface direction. When the magnetic head includes such mechanism, a distance between the magnetic head and a magnetic layer of the medium is reduced, and hence a signal from smaller magnetic particles can be picked up. Thus, the increase in recording density can be achieved. Meanwhile, the gap between the recording/reproducing element portion of the magnetic head and the surface of the magnetic recording medium becomes as extremely small as, for example, 2 nm or less, and hence the magnetic head may collide with the surface of the magnetic recording medium even with a small impact. This tendency becomes remarkable as the rotation speed is increased. Accordingly, at the time of high-speed rotation, it is important to prevent the occurrence of deflection or vibration (fluttering) of the glass sheet, which causes the collision.

Further, in order to achieve an increase in Ku by increasing the degree of ordering (ordering degree) of the magnetic layer, a base material including a glass sheet may be subjected to heat treatment at a high temperature of about 800° C. at the time of the formation of the magnetic layer, or before or after the formation. The heat treatment temperature needs to be a higher temperature as the recording density is increased, and hence higher heat resistance, that is, a higher strain point than that of the related-art glass sheet for a magnetic recording medium is required. In addition, after the magnetic layer is formed, the base material including the glass sheet may be subjected to laser irradiation. Such heat treatment or laser irradiation has a purpose of increasing the annealing temperature or coercive force of a magnetic layer containing an FePt-based alloy or the like.

However, as described above, when the Young's modulus and strain point of the glass sheet are to be increased, the glass composition loses its balance, with the result that the productivity is reduced, and particularly the devitrification resistance is remarkably reduced, and the glass sheet cannot be formed by an overflow down-draw method owing to an increase in liquidus temperature. In addition, the meltability is reduced or a glass forming temperature is increased, with the result that the lifetime of a forming trough is liable to be shortened. As a result, the raw sheet cost of the glass sheet rises.

Thus, the present invention has been devised in view of the above-mentioned circumstances, and a technical object of the present invention is to provide an alkali-free glass sheet, which is excellent in productivity, and which has high durability to BHF, and a sufficiently high strain point and a sufficiently high Young's modulus.

### Solution to Problem

(1) According to one embodiment of the present invention, there is provided an alkali-free glass sheet, comprising as a glass composition, in terms of mols, 65% to 72% of SiO₂, 11% to 15% of Al₂O₃, 2% to 5% of B₂O₃, 0% to 0.5% of Li₂O+Na₂O+K₂O, 2% to 8% of MgO, 4% to 10% of CaO, 0% to 4% of SrO, 0% to 4% of BaO, and 11% to 17% of MgO+CaO+SrO+BaO, and having a mole percent ratio (MgO+CaO+SrO+BaO−Al₂O₃)/B₂O₃ of from 0.2 to 1, a mole percent ratio SrO/CaO of from 0 to 0.6, a mole percent ratio BaO/CaO of from 0 to 0.6, and a value determined from the formula 0.116×[Al₂O₃]−0.079×[B₂O₃]+0.155×[MgO]+0.299×[CaO]+0.336×[SrO]+0.385×[BaO] of from 2% to 8%. Herein, the “Li₂O+Na₂O+K₂O” refers to the total content of Li₂O, Na₂O, and K₂O. The “MgO+CaO+SrO+BaO” refers to the total of the contents of MgO, CaO, SrO, and BaO in terms of mols. The “(MgO+CaO+SrO+BaO−Al₂O₃)/B₂O₃” refers to a value obtained by: subtracting the content of Al₂O₃ in terms of mole from the total of the contents of MgO, CaO, SrO, and BaO in terms of mol %; and dividing the resultant by the content of B₂O₃ in terms of mole. The “SrO/CaO” refers to a value obtained by dividing the content of SrO in terms of mol % by the content of CaO in terms of mol %. The “BaO/CaO” refers to a value obtained by dividing the content of BaO in terms of mole by the content of CaO in terms of mol %. The “alkali-free glass” as used in the present invention refers to a glass having a content of Li₂O+Na₂O+K₂O of 0.5% or less.
(2) In the above-mentioned configuration (1), it is preferred that the alkali-free glass sheet comprise, as the glass composition, in terms of mol %, 66% to 71% of SiO₂, 12% to 14% of Al₂O₃, 2.5% to 4% of B₂O₃, 0% to 0.1% of Li₂O+Na₂O+K₂O, 3% to 7% of MgO, 5% to 9% of CaO, 0.1% to 3% of SrO, 0.1% to 3% of BaO, and 12% to 16% of MgO+CaO+SrO+BaO, and have a mole percent ratio (MgO+CaO+SrO+BaO-Al₂O₃)/B₂O₃ of from 0.2 to 0.65, a mole percent ratio SrO/CaO of from 0 to 0.32, a mole percent ratio BaO/CaO of from 0 to 0.25, and a value determined from the formula 0.116×[Al₂O₃]−0.079×[B₂O₃]+0.155×[MgO]+0.299×[CaO]+0.336×[SrO]+0.385×[BaO] of from 4.6% to 7%.
(3) In the above-mentioned configuration (1) or (2), it is preferred that the alkali-free glass sheet be substantially free of As₂O₃ and Sb₂O₃ in the glass composition, and further comprise 0.001 mol % to 1 mol % of SnO₂. Herein, the “substantially free of As₂O₃” refers to a case in which the content of As₂O₃ is 0.05 mol % or less. The “substantially free of Sb₂O₃” refers to a case in which the content of Sb₂O₃ is 0.05 mol % or less.
(4) In any one of the above-mentioned configurations (1) to (3), it is preferred that the alkali-free glass sheet have a Young's modulus of 81 GPa or more, a strain point of 720° C. or more, and a liquidus temperature of 1,400° C. or less. Herein, the “Young's modulus” refers to a value measured by a flexural resonance method. 1 GPa corresponds to about 101.9 Kgf/mm². The “strain point” refers to a value measured based on a method specified in ASTM C336. The “liquidus temperature” refers to the highest temperature at which a crystal precipitates after glass powder that has passed through a standard 30-mesh sieve (500 μm) and remained on a 50-mesh sieve (300 μm) is placed in a platinum boat and kept for 24 hours in a gradient heating furnace.
(5) In any one of the above-mentioned configurations (1) to (4), it is preferred that the alkali-free glass sheet have a strain point of 725° C. or more.
(6) In any one of the above-mentioned configurations (1) to (5), it is preferred that the alkali-free glass sheet have a Young's modulus of more than 82 GPa.
(7) In any one of the above-mentioned configurations (1) to (6), it is preferred that the alkali-free glass sheet have a specific Young's modulus of 31 GPa/g·cm or more. Herein, the “specific Young's modulus” refers to a value obtained by dividing the Young's modulus by a density.
(8) In any one of the above-mentioned configurations (1) to (7), it is preferred that the alkali-free glass sheet have an average thermal expansion coefficient within a temperature range of from 30° C. to 380° C. of from 30×10⁻⁷/° C. to 50×10⁻⁷/° C. Herein, the “average thermal expansion coefficient within a temperature range of from 30° C. to 380° C.” may be measured with a dilatometer.
(9) In any one of the above-mentioned configurations (1) to (8), it is preferred that the alkali-free glass sheet have an annealing point of 780° C. or more. Herein, the “annealing point” refers to a value measured based on a method specified in ASTM C336.
(10) In any one of the above-mentioned configurations (1) to (9), it is preferred that the alkali-free glass sheet have a liquidus viscosity of 10^{3.9} dPa·s or more. Herein, the “liquidus viscosity” refers to a glass viscosity at the liquidus temperature, and may be measured by a platinum sphere pull up method.
(11) In any one of the above-mentioned configurations (1) to (10), it is preferred that the alkali-free glass sheet be used for an OLED device.
(12) In any one of the above-mentioned configurations (1) to (10), it is preferred that the alkali-free glass sheet be used for an information recording medium.

### Advantageous Effects of Invention

The alkali-free glass sheet of the present invention is excellent in productivity, and has high durability to BHF, and a sufficiently high strain point and a sufficiently high Young's modulus.

### BRIEF DESCRIPTION OF DRAWINGS

FIG. 1 is an upper perspective view for illustrating an example of the shape of a glass substrate for a magnetic recording medium.

### DESCRIPTION OF EMBODIMENTS

An alkali-free glass sheet of the present invention comprises as a glass composition, in terms of mol %, 651 to 72% of SiO₂, 11% to 15% of Al₂O₃, 2% to 5% of B₂O₃, 0% to 0.5% of Li₂O+Na₂O+K₂O, 2% to 8% of MgO, 4% to 10% of CaO, 0% to 4% of SrO, 0% to 4% of BaO, and 11% to 17% of MgO+CaO+SrO+BaO, and has a mole percent ratio (MgO+CaO+SrO+BaO−Al₂O₃)/B₂O₃ of from 0.2 to 1, a mole percent ratio SrO/CaO of from 0 to 0.6, a mole percent ratio BaO/CaO of from 0 to 0.6, and a value determined from the formula 0.116×[Al₂O₃]−0.079×[B₂O₃]+0.155×[MgO]+0.299×[CaO]+0.336×[SrO]+0.385×[BaO] of from 2% to 8%. The reasons why the contents of the components are limited as described above are described below. In the descriptions of the contents of the components, the expression “%” represents “mol %”, unless otherwise specified. In addition, the upper limit of the content means that the content is equal to or less than its value, and the lower limit of the content means that the content is equal to or more than its value, unless otherwise specified.

SiO₂ is a component that forms the skeleton of glass. When the content of SiO₂ is too small, a thermal expansion coefficient is increased, and a density is increased. Accordingly, the lower limit content of SiO₂ is preferably 65%, more preferably 65.1%, still more preferably 65.2%, still more preferably 65.4%, still more preferably 65.6%, still more preferably 65.8%, still more preferably 65.9%, still more preferably 66%, still more preferably 66.1%, still more preferably 66.2%, still more preferably 66.3%, still more preferably 66.4%, still more preferably 66.5%, still more preferably 66.6%, still more preferably 66.8%, still more preferably 67%, still more preferably 67.2%, still more preferably 67.4%, still more preferably 67.63, still more preferably 67.8%, particularly preferably 68%. Meanwhile, when the content of SiO₂ is too large, a Young's modulus is reduced. Further, a viscosity at high temperature is increased, resulting in an increase in amount of heat required for melting. This causes a rise in melting cost, and leads to occurrence of an unmelted residue of a raw material for introducing SiO₂, which may cause a reduction in yield. In addition, a devitrified crystal such as cristobalite is liable to precipitate, and a liquidus viscosity is liable to be reduced. Accordingly, the upper limit content of SiO₂ is preferably 72%, more preferably 71.8%, still more preferably 71.6%, still more preferably 71.4%, still more preferably 71.2%, still more preferably 71%, still more preferably 70.8%, still more preferably 70.6%, still more preferably 70.4%, still more preferably 70.2%, still more preferably 70%, particularly preferably 69.8%.

Al₂O₃ is a component that forms the skeleton of the glass, is also a component that increases the Young's modulus, and is also a component that increases a strain point. When the content of Al₂O₃ is too small, the Young's modulus is liable to be reduced, and the strain point is liable to be reduced. Accordingly, the lower limit content of Al₂O₃ is preferably 11%, more preferably 11.2%, still more preferably 11.4%, still more preferably 11.5%, still more preferably 11.6%, still more preferably 11.8%, still more preferably 12%, still more preferably 12.1%, still more preferably 12.25, still more preferably 12.3%, still more preferably 12.4%, particularly preferably 12.5%. Meanwhile, when the content of Al₂O₃ is too large, a devitrified crystal such as mullite is liable to precipitate, and the liquidus viscosity is liable to be reduced. Accordingly, the upper limit content of Al₂O₃ is preferably 15%, more preferably 14.8%, still more preferably 14.6%, still more preferably 14.4%, still more preferably 14.25, still more preferably 14%, still more preferably 13.9%, still more preferably 13.8%, still more preferably 13.7%, particularly preferably 13.6%.

The mole percent ratio SiO₂/Al₂O₃ is an important component ratio for increasing the strain point and reducing the viscosity at high temperature. When the mole percent ratio SiO₂/Al₂O₃ is too small, the strain point is liable to be reduced. Accordingly, the lower limit value of the mole percent ratio SiO₂/Al₂O₃ is preferably 4.5, more preferably 4.7, still more preferably 4.9, still more preferably 5, still more preferably 5.1, still more preferably more than 5.1, particularly preferably 5.2. Meanwhile, when the mole percent ratio SiO₂/Al₂O₃ is too large, the viscosity at high temperature is increased, and the manufacturing cost of the glass sheet is liable to rise. Accordingly, the upper limit value of the mole percent ratio SiO₂/Al₂O₃ is preferably 6.5, more preferably 6.3, still more preferably 6.1, still more preferably 6, still more preferably 5.9, still more preferably 5.8, still more preferably 5.7, still more preferably 5.6, still more preferably 5.5, particularly preferably 5.4.

B₂O₃ is a component that improves durability to BHF, and can exhibit improving effects on the meltability and the devitrification resistance. Accordingly, the lower limit content of B₂O₃ is preferably 2%, more preferably 2.1%, still more preferably 2.2%, still more preferably 2.3%, still more preferably 2.4%, particularly preferably 2.5%. Meanwhile, when the content of B₂O₃ is too large, the Young's modulus and the strain point are liable to be reduced. Accordingly, the upper limit content of B₂O₃ is preferably 5%, more preferably 4.9%, still more preferably 4.8%, still more preferably 4.7%, still more preferably 4.6%, still more preferably 4.5%, still more preferably 4.4%, still more preferably 4.3%, still more preferably 4.2%, still more preferably 4.1%, still more preferably 4%, still more preferably less than 4%, still more preferably 3.9%, still more preferably 3.8%, particularly preferably 3.7%.

The mole percent ratio B₂O₃/Al₂O₃ is an important component ratio for increasing the Young's modulus, increasing the strain point, and improving the durability to BHF. When the mole percent ratio B₂O₃/Al₂O₃ is too small, the Young's modulus is liable to be reduced. Accordingly, the lower limit value of the mole percent ratio B₂O₃/Al₂O₃ is preferably 0, more preferably 0.13, still more preferably 0.135, still more preferably 0.15, still more preferably 0.18, still more preferably 0.2, particularly preferably 0.22. Meanwhile, when the mole percent ratio B₂O₃/Al₂O₃ is too large, the strain point is liable to be reduced. Accordingly, the upper limit value of the mole percent ratio B₂O₃/Al₂O₃ is preferably 0.3, more preferably less than 0.3, still more preferably 0.29, still more preferably less than 0.29, still more preferably 0.28, still more preferably less than 0.28, particularly preferably 0.27.

Li₂O, Na₂O, and K₂O are each a component that is inevitably mixed in from glass raw materials, and the total content thereof falls within the range of from 0% to 0.5%, preferably from 0% to 0.1%, more preferably from 0% to 0.09%, still more preferably from 0.005% to 0.08%, still more preferably from 0.008% to 0.06%, particularly preferably from 0.01 to 0.05%. When the total content of Li₂O, Na₂O, and K₂O is too large, a situation in which an alkali ion is diffused into a semiconductor substance formed into a film in a heat treatment step may occur. The individual contents of Li₂O, Na₂O, and K₂O each fall within the range of preferably from 0% to 0.3%, more preferably from 0% to 0.10, still more preferably from 0% to 0.080, still more preferably from 0% to 0.07%, still more preferably from 0% to 0.05%, particularly preferably from 0.001% to 0.04%.

MgO is a component that remarkably increases the Young's modulus among alkaline earth metal oxides. When the content of MgO is too small, the meltability and the Young's modulus are liable to be reduced. Accordingly, the lower limit content of MgO is preferably 2%, more preferably 2.1%, more preferably 2.3%, still more preferably 2.5%, still more preferably 2.8%, still more preferably 3%, still more preferably 3.3%, particularly preferably 3.5%. Meanwhile, when the content of MgO is too large, a devitrified crystal such as mullite is liable to precipitate, and the liquidus viscosity is liable to be reduced. Accordingly, the upper limit content of MgO is preferably 8%, more preferably 7.8%, more preferably 7.6%, more preferably 7.5%, more preferably 7.4%, more preferably less than 7.3%, more preferably 7.2%, more preferably 7.1%, still more preferably 7.0%, still more preferably 6.9%, particularly preferably 6.8%.

CaO is a component that reduces the viscosity at high temperature to remarkably improve the meltability without reducing the strain point. CaO is also a component that increases the Young's modulus. When the content of CaO is too small, the meltability is liable to be reduced. Accordingly, the lower limit content of CaO is preferably 4%, more preferably 4.2%, still more preferably 4.3%, still more preferably 4.5%, still more preferably 4.6%, still more preferably 4.7%, still more preferably 5%, still more preferably 5.2%, particularly preferably 5.5%. Meanwhile, when the content of CaO is too large, the liquidus temperature is increased. Accordingly, the upper limit content of CaO is preferably 10%, more preferably 9.8%, still more preferably 9.5%, still more preferably 9.2%, still more preferably 9%, still more preferably 8.9%, still more preferably 8.7%, particularly preferably 8.5%.

The mole percent ratio MgO/CaO is an important component ratio for increasing the Young's modulus. When the mole percent ratio MgO/CaO is too small, the Young's modulus is liable to be reduced. Accordingly, the lower limit value of the mole percent ratio MgO/CaO is preferably 0.2, more preferably 0.21, still more preferably 0.22, still more preferably 0.23, still more preferably 0.24, particularly preferably 0.25. Meanwhile, when the mole percent ratio MgO/CaO is too large, the devitrification resistance is liable to be reduced. Accordingly, the upper limit value of the mole percent ratio MgO/CaO is preferably 1.5, more preferably 1.4, still more preferably 1.3, still more preferably 1.2, still more preferably 1.1, still more preferably 1, still more preferably 0.95, still more preferably 0.94, particularly preferably 0.935.

SrO is a component that improves the devitrification resistance, and reduces the viscosity at high temperature to improve the meltability without reducing the strain point. SrO is also a component that suppresses a reduction in liquidus viscosity. Accordingly, the lower limit content of SrO is preferably 0%, more preferably more than 0%, more preferably 0.1%, still more preferably more than 0.1%, still more preferably 0.2%, still more preferably 0.3%, still more preferably more than 0.3%, still more preferably 0.4%, still more preferably more than 0.4%, particularly preferably 0.5%. Meanwhile, when the content of SrO is too large, the thermal expansion coefficient and the density are liable to be increased. Accordingly, the upper limit content of SrO is preferably 4%, more preferably less than 4%, still more preferably 3.8%, still more preferably 3.5%, still more preferably 3.3%, still more preferably 3%, still more preferably 2.8%, still more preferably 2.5%, still more preferably 2.3%, particularly preferably 2%.

The mole percent ratio SrO/CaO is an important component ratio for improving the durability to BHF. When the mole percent ratio SrO/CaO is too small, the meltability is reduced, and the manufacturing cost of the glass sheet is liable to rise. Accordingly, the lower limit value of the mole percent ratio SrO/CaO is preferably 0, more preferably 0.01, still more preferably 0.02, still more preferably 0.03, still more preferably 0.04, still more preferably 0.05, still more preferably 0.06, still more preferably 0.07, still more preferably 0.08, still more preferably 0.09, particularly preferably 0.1. Meanwhile, when the mole percent ratio SrO/CaO is too large, the durability to BHF is liable to be reduced. Accordingly, the upper limit value of the mole percent ratio SrO/CaO is preferably 0.6, more preferably 0.55, still more preferably 0.53, still more preferably 0.5, still more preferably 0.48, still more preferably 0.45, still more preferably 0.43, still more preferably 0.4, still more preferably 0.38, still more preferably 0.35, still more preferably 0.33, still more preferably 0.32, still more preferably 0.31, still more preferably 0.3, still more preferably 0.29, still more preferably 0.28, particularly preferably 0.25.

BaO is a component that improves the devitrification resistance. Accordingly, the lower limit content of BaO is preferably 0%, more preferably more than 0%, more preferably 0.1%, still more preferably more than 0.1%, still more preferably 0.2%, still more preferably 0.3%, still more preferably 0.4%, still more preferably more than 0.4%, particularly preferably 0.5%. Meanwhile, when the content of BaO is too large, the Young's modulus is liable to be reduced, and the density is liable to be increased. As a result, a specific Young's modulus is reduced, and the glass sheet is liable to be deflected. Accordingly, the upper limit content of BaO is preferably 4%, more preferably less than 4%, still more preferably 3.8%, still more preferably 3.5%, still more preferably 3.3%, still more preferably 3%, still more preferably 2.8%, still more preferably 2.5%, still more preferably 2.3%, particularly preferably 2%.

The mole percent ratio BaO/CaO is an important component ratio for increasing the specific Young's modulus. When the mole percent ratio BaO/CaO is too small, the devitrification resistance is reduced, and the manufacturing cost of the glass sheet is liable to rise. Accordingly, the lower limit value of the mole percent ratio BaO/CaO is preferably 0, more preferably more than 0, still more preferably 0.001, still more preferably 0.002, still more preferably 0.004, still more preferably 0.006, still more preferably 0.008, still more preferably 0.01, still more preferably 0.012, still more preferably 0.014, still more preferably 0.016, still more preferably 0.018, still more preferably 0.02, still more preferably 0.022, still more preferably 0.024, still more preferably 0.026, still more preferably 0.028, still more preferably 0.03, particularly preferably 0.032. Meanwhile, when the mole percent ratio BaO/CaO is too large, the specific Young's modulus is liable to be reduced. Accordingly, the upper limit value of the mole percent ratio BaO/CaO is preferably 0.6, more preferably 0.55, still more preferably 0.53, still more preferably 0.5, still more preferably 0.48, still more preferably 0.45, still more preferably 0.43, still more preferably 0.4, still more preferably 0.38, still more preferably 0.35, still more preferably 0.33, still more preferably 0.3, still more preferably 0.29, still more preferably 0.28, particularly preferably 0.25.

MgO, CaO, SrO, and BaO are each a component that increases the density and the thermal expansion coefficient. When the content of MgO+CaO+SrO+BaO is too small, the thermal expansion coefficient is liable to be reduced. Accordingly, the lower limit content of MgO+CaO+SrO+BaO is preferably 11%, more preferably 11.2%, more preferably 11.5%, still more preferably 11.8%, still more preferably 12%, still more preferably 12.3%, still more preferably 12.5%, still more preferably 12.8%, particularly preferably 13%. Meanwhile, when the content of MgO+CaO+SrO+BaO is too large, the density is liable to be increased. Accordingly, the upper limit content of MgO+CaO+SrO+BaO is preferably 17%, more preferably 16.8%, more preferably 16.5%, still more preferably less than 16.5%, still more preferably 16.3%, still more preferably 16.1%, particularly preferably 16%.

The mole percent ratio (MgO+CaO+SrO+BaO−Al₂O₃)/B₂O₃ is an important component ratio relating to the durability to BHF and the meltability. The alkaline earth metal oxide is a component that cuts a network structure in the glass. In contrast, B₂O₃ is a component that forms the network structure in the glass. The alkaline earth metal oxide has a cutting effect on the network structure in the glass, but Al₂O₃ forms the network structure in the glass, and hence the alkaline earth metal oxide at the same content as the content of Al₂O₃ does not have the cutting effect on the network. That is, as the mole percent ratio (MgO+CaO+SrO+BaO−Al₂O₃)/B₂O₃ becomes smaller, the content of the component that cuts the network structure becomes smaller with respect to the content of the component that forms the network structure, and hence chemical durability, in particular, the durability to BHF is improved. When the mole percent ratio (MgO+CaO+SrO+BaO−Al₂O₃)/B₂O₃ is too small, the meltability is liable to be reduced, and the manufacturing cost of the glass sheet is liable to rise. Accordingly, the lower limit value of the mole percent ratio (MgO+CaO+SrO+BaO−Al₂O₃)/B₂O₃ is preferably 0.2, more preferably 0.21, still more preferably 0.22, still more preferably 0.23, still more preferably 0.24, still more preferably 0.25, still more preferably 0.26, still more preferably 0.27, particularly preferably 0.28. Meanwhile, when the mole percent ratio (MgO+CaO+SrO+BaO−Al₂O₃)/B₂O₃ is too large, the durability to BHF is liable to be reduced. Accordingly, the upper limit value of the mole percent ratio (MgO+CaO+SrO+BaO−Al₂O₃)/B₂O₃ is preferably 1, more preferably 0.9, still more preferably 0.85, still more preferably 0.8, still more preferably 0.75, still more preferably 0.7, particularly preferably 0.65.

The value determined from the formula 0.116×[Al₂O₃]−0.079×[B₂O_{3]+0.155}×[MgO]+0.299−[CaO]+0.336×[SrO]+0.385×[BaO] is an important component formula value relating to the durability to BHF and the meltability. When the value determined from the formula 0.116×[Al₂O₃]−0.079×[B₂O_{3]+0.155}×[MgO]+0.299×[CaO]+0.336×[SrO]+0.385−[BaO] is too small, the meltability is liable to be reduced, and the manufacturing cost of the glass sheet is liable to rise. Accordingly, the lower limit of the value determined from the formula 0.116×[Al₂O₃]−0.079×[B₂O_{3]+0.155}×[MgO]+0.299−[CaO]+0.336×[SrO]+0.385×[BaO] is preferably 2%, more preferably 2.5%, still more preferably 3%, still more preferably 3.5%, still more preferably 3.8%, still more preferably 4%, still more preferably 4.2%, still more preferably 4.4%, still more preferably 4.6%, particularly preferably 4.7%. Meanwhile, when the value determined from the formula 0.116×[Al₂O₃]−0.079×[B₂O₃]+0.155×[MgO]+0.299×[CaO]+0.336×[SrO]+0.385×[BaO] is too large, the durability to BHF is liable to be reduced. Accordingly, the upper limit of the value determined from the formula 0.116×[Al₂O₃]−0.079×[B₂O₃]+0.155×[MgO]+0.299×[CaO]+0.336×[SrO]+0.385×[BaO] is preferably 8%, more preferably 7.8%, still more preferably 7.5%, still more preferably 7.3%, still more preferably 7%, still more preferably 6.8%, still more preferably 6.5%, still more preferably 6.3%, still more preferably 6%, still more preferably 5.8%, still more preferably 5.7%, still more preferably 5.6%, still more preferably 5.5%, still more preferably 5.4%, still more preferably 5.3%, still more preferably 5.2%, particularly preferably 5%.

Suitable content ranges of the components may be freely combined to provide suitable glass composition ranges. Of those, the following glass composition range is particularly preferred to optimize the effects of the invention of the present application: the alkali-free glass sheet comprises, as a glass composition, in terms of mol %, 66% to 71% of SiO₂, 12% to 14% of Al₂O₃, 2.5% to 4% of B₂O₃, 0% to 0.1% of Li₂O+Na₂O+K₂O, 3% to 7% of MgO, 5, to 9% of CaO, 0.1% to 3% of SrO, 0.1% to 3% of BaO, and 12% to 16% of MgO+CaO+SrO+BaO, and has a mole percent ratio (MgO+CaO+SrO+BaO−Al₂O₃)/B₂O₃ of from 0.2 to 0.65, a mole percent ratio SrO/CaO of from 0 to 0.32, a mole percent ratio BaO/CaO of from 0 to 0.25, and a value determined from the formula 0.116−[Al₂O₃]−0.079×[B₂O_{3]+0.155}×[MgO]+0.299−[CaO]+0.336×[SrO]+0.385×[BaO] of from 4.6% to 7%.

For example, the following components may be added as optional components in addition to the above-mentioned components. The content of the components other than the above-mentioned components, in terms of total content, is preferably 10% or less, particularly preferably 5% or less from the viewpoint of appropriately exhibiting the effects of the present invention.

P₂O₅ is a component that increases the strain point, and is also a component that can remarkably suppress the precipitation of an alkaline earth aluminosilicate-based devitrified crystal such as anorthite. However, when P₂O₅ is incorporated in a large amount, the glass is liable to undergo phase separation. The content of P₂O₅ falls within the range of preferably from 0% to 2.5%, more preferably from 0% to 1.5%, still more preferably from 0% to 0.5%, still more preferably from 0% to 0.3%, still more preferably from 0% to less than 0.1%, particularly preferably from 0% to less than 0.01%.

TiO₂ is a component that reduces the viscosity at high temperature to improve the meltability, and is also a component that suppresses solarization. However, when TiO₂ is incorporated in a large amount, the glass is colored, and thus a transmittance is liable to be reduced. The content of TiO₂ falls within the range of preferably from 0% to 2.5%, more preferably from 0.0005% to 1%, still more preferably from 0.001, to 0.5%, particularly preferably from 0.005% to 0.1%.

ZnO is a component that increases the Young's modulus. However, when ZnO is incorporated in a large amount, the glass is liable to devitrify, and the strain point is liable to be reduced. The content of ZnO falls within the range of preferably from 0% to 3%, more preferably from 0% to 2%, still more preferably from 0% to 1%, still more preferably from 0%, to 0.8%, still more preferably from 0% to 0.5%, particularly preferably from 0% to less than 0.5%.

Fe₂O₃ is a component that is inevitably mixed in from glass raw materials, and is also a component that reduces an electrical resistivity. The content of Fe₂O₃ falls within the range of preferably from 0 mol ppm to 250 mol ppm or from 20 mol ppm to 200 mol ppm, particularly preferably from 40 mol ppm to 100 mol ppm. When the content of Fe₂O₃ is too small, the raw material cost is liable to rise. Meanwhile, when the content of Fe₂O₃ is too large, it becomes difficult to perform electric melting owing to an increase in electrical resistivity of the molten glass.

ZrO₂ is a component that increases the Young's modulus. However, when ZrO₂ is incorporated in a large amount, the glass is liable to devitrify. The content of ZrO₂ falls within the range of preferably from 0% to 2.5%, more preferably from 0.0005% to 1%, still more preferably from 0.001% to 0.5%, particularly preferably from 0.005% to 0.1%.

MoO₃ is a component that absorbs UV light (light having a wavelength of from 200 nm to 300 nm). In addition, MoO₃ is a component that reduces the amount of water in the glass. Particularly when a raw material batch is melted by electric melting heating, and MoO₃ is incorporated, the amount of water in the glass can be further reduced. When the amount of water in the glass is reduced, the liquidus viscosity and the strain point are increased, and the devitrification resistance and heat resistance of the glass can be improved. The lower limit content of MoO₃ is preferably 0.00001%, more preferably 0.00005%, still more preferably 0.00010, still more preferably 0.0002%, still more preferably 0.0003%, still more preferably 0.0004%, particularly preferably 0.001%. Meanwhile, when the content of MoO₃ is too large, the transmittance of UV light is reduced, and hence a reduction in yield is liable to occur particularly in a laser peeling step in a manufacturing process for a display. Accordingly, the content is preferably 0.01%, more preferably 0.008%, still more preferably 0.006%, still more preferably 0.005%, particularly preferably 0.003%.

Y₂O₃, Nb₂O₅, and La₂O₃ have increasing actions on the strain point, the Young's modulus, and the like. The total content and individual contents of those components each fall within the range of preferably from 0% to 5%, more preferably from 0% to 1%, still more preferably from 0% to 0.5% particularly preferably from 0% to less than 0.5%. When the total content and individual contents of Y₂O₃, Nb₂O₅, and La₂O₃ are too large, the density and raw material cost are liable to be increased.

SnO₂ is a component that has a satisfactory fining action in a high temperature region. In addition, SnO₂ is a component that increases the strain point, and is also a component that reduces the viscosity at high temperature. The content of SnO₂ falls within the range of preferably from 0% to 1%, from 0.001% to 1%, or from 0.01, to 0.5%, particularly preferably from 0.05% to 0.3%. When the content of SnO₂ is too large, a devitrified crystal of SnO₂ is liable to precipitate. When the content of SnO₂ is less than 0.001%, it becomes difficult to exhibit the above-mentioned effects.

SnO₂ is suitable as a fining agent as described above, but unless glass characteristics are impaired, F, SO₃, C, or metal powder of Al, Si, or the like may each be added as a fining agent in place of SnO₂ or together with SnO₂ at up to 5% (preferably up to 1%, particularly preferably up to 0.5%). In addition, CeO₂, F, or the like may also be added as a fining agent at up to 5% (preferably up to 1%, particularly preferably up to 0.5%).

As₂O₃ and Sb₂O₃ are each effective as a fining agent as well. However, As₂O₃ and Sb₂O₃ are each a component that increases an environmental load. In addition, As₂O₃ is a component that reduces solarization resistance. Accordingly, it is preferred that the alkali-free glass sheet of the present invention be substantially free of those components.

Cl is a component that promotes initial melting of a glass batch. In addition, when Cl is added, the action of the fining agent can be promoted. As a result thereof, while the melting cost is reduced, the lifetime of a glass production kiln can be prolonged. However, when the content of Cl is too large, the strain point is liable to be reduced. Accordingly, the content of Cl falls within the range of preferably from 0% to 3%, more preferably from 0.0005% to 1%, particularly preferably from 0.001% to 0.5%. The following raw material may be used as a raw material for introducing Cl: an alkaline earth metal chloride such as strontium chloride, aluminum chloride, or the like.

The alkali-free glass sheet of the present invention preferably has the following characteristics.

The average thermal expansion coefficient within a temperature range of from 30° C. to 380° C. is preferably from 30×10⁻⁷/° C. to 50×10⁻⁷/° C., more preferably from 32×10⁻⁷/° C. to 48×10⁻⁷/° C., still more preferably from 33×10⁻⁷/° C. to 45×10⁻⁷/° C., still more preferably from 34×10⁻⁷/° C. to 44×10⁻⁷/° C., particularly preferably from 35×10⁻⁷/° C. to 43×10⁻⁷/° C. With this configuration, the thermal expansion coefficient easily matches the thermal expansion coefficient of Si to be used for a TFT.

The Young's modulus is preferably 81 GPa or more, more preferably more than 81 GPa, still more preferably 81.3 GPa or more, still more preferably 81.5 GPa or more, still more preferably 81.8 GPa or more, still more preferably 82 GPa or more, still more preferably 82.3 GPa or more, still more preferably 82.5 GPa or more, still more preferably 82.8 GPa or more, particularly preferably 83 GPa or more. When the Young's modulus is too low, defects due to the deflection of the glass sheet are liable to occur. In addition, the Young's modulus is preferably 120 GPa or less, more preferably 110 GPa or less, still more preferably 100 GPa or less, particularly preferably 95 GPa or less.

The specific Young's modulus is preferably 31 GPa/g·cm⁻³ or more, more preferably 31.1 GPa/g·cm⁻³ or more, still more preferably 31.3 GPa/g·cm⁻³ or more, still more preferably 31.5 GPa/g·cm⁻³ or more, still more preferably 31.8 GPa/g·cm⁻³ or more, still more preferably 32 GPa/g·cm⁻³ or more, still more preferably 32.2 GPa/g·cm⁻³ or more, still more preferably 32.4 GPa/g·cm⁻³ or more, still more preferably 32.4 GPa/g·cm⁻³ or more, still more preferably 32.8 GPa/g·cm⁻³ or more, particularly preferably 33 GPa/g·cm⁻³ or more. When the specific Young's modulus is too low, defects due to the deflection of the glass sheet are liable to occur. In addition, the specific Young's modulus is preferably 37 GPa/g·cm⁻³ or less, more preferably 36.5 GPa/g·cm⁻³ or less, still more preferably 36 GPa/g·cm⁻³ or less, still more preferably 35.7 GPa/g·cm⁻³ or less, particularly preferably 35.0 GPa/g·cm³ or less.

The strain point is preferably 710° C. or more, more preferably 715° C. or more, still more preferably 718° C. or more, still more preferably 720° C. or more, still more preferably 725° C. or more, still more preferably 728° C. or more, still more preferably 730° C. or more, still more preferably 735° C. or more, still more preferably 740° C. or more, particularly preferably 745° C. or more. With this configuration, the thermal shrinkage of the glass sheet can be suppressed in a LTPS process. In addition, the strain point is preferably 820° C. or less, more preferably 815° C. or less, still more preferably 810° C. or less, particularly preferably 800° C. or less.

The annealing point is preferably 770° C. or more, more preferably 775° C. or more, still more preferably 780° C. or more, still more preferably 782° C. or more, still more preferably 785° C. or more, particularly preferably 790° C. or more. With this configuration, the thermal shrinkage of the glass sheet can be suppressed in the LTPS process. The annealing point is preferably 900° C. or less, more preferably 890° C. or less, still more preferably 880° C. or less, particularly preferably 870° C. or less.

The liquidus temperature is preferably 1,400° C. or less, more preferably 1,380° C. or less, still more preferably 1,350° C. or less, still more preferably 1,300° C. or less, still more preferably 1,290° C. or less, still more preferably 1,285° C. or less, still more preferably 1,280° C. or less, still more preferably 1,275° C. or less, particularly preferably 1,270° C. or less. The liquidus temperature is preferably 1,160° C. or more, more preferably 1,170° C. or more, particularly preferably 1,180° C. or more. With this configuration, a situation in which a devitrified crystal is generated at the time of glass manufacture, resulting in a reduction in productivity, is easily prevented. Further, the glass sheet is easily formed by an overflow down-draw method, and hence the surface quality of the glass sheet is easily improved. In addition, the manufacturing cost of the glass sheet can be reduced. The liquidus temperature serves as an indicator of the devitrification resistance. As the liquidus temperature becomes lower, the devitrification resistance is more excellent.

The liquidus viscosity is preferably 10⁻⁶ dPa·s or more, more preferably 10^{3.8} dPa·s or more, still more preferably 10^{4.0} dPa·s or more, still more preferably 10^{4.2} dPa·s or more, still more preferably 10^{-4.4} dPa·s or more, still more preferably 10^{4.6} dPa·s or more, still more preferably 10^{4.8} dPa·s or more, still more preferably 10^{5.0} dPa·s or more, particularly preferably 10^{5.1} dPa·s or more. The liquidus viscosity is preferably 10^{7.4} dPa·s or less, more preferably 10^{7.2} dPa·s or less, particularly preferably 10^{7.0} dPa·s or less. With this configuration, devitrification is less liable to occur at the time of forming, and hence the glass sheet is easily formed by an overflow down-draw method. As a result, the surface quality of the glass sheet can be improved. In addition, the manufacturing cost of the glass sheet can be reduced. The liquidus viscosity serves as indicators of the devitrification resistance and the formability. As the liquidus viscosity becomes higher, the devitrification resistance and the formability are improved more.

The temperature at a viscosity at high temperature of 10^{2.5} dPa·s is preferably 1,700° C. or less, more preferably 1,680° C. or less, still more preferably 1,660° C. or less, particularly preferably 1,650° C. or less. The temperature at a viscosity at high temperature of 10^{2.5} dPa·s is preferably 1,560° C. or more, more preferably 1,570° C., still more preferably 1,580° C., particularly preferably 1,590° C. When the temperature at a viscosity at high temperature of 10^{2.5} dPa·s is too high, it becomes difficult to melt a glass batch, resulting in a rise in manufacturing cost of the glass sheet. The temperature at a viscosity at high temperature of 10^{2.5} dPa·s corresponds to a melting temperature. As the temperature becomes lower, the meltability is improved more.

A β-OH value is an indicator of the amount of water in the glass. When the β-OH value is reduced, the strain point can be increased. In addition, even with the same glass composition, a glass sheet having a smaller β-OH value has a lower thermal shrinkage rate at a temperature equal to or lower than the strain point. The β-OH value is preferably 0.35/mm or less, more preferably 0.30/mm or less, still more preferably 0.28/mm or less, still more preferably 0.25/mm or less, still more preferably 0.20/mm or less, still more preferably 0.17/mm or less, particularly preferably 0.15/mm or less. When the β-OH value is too small, the meltability is liable to be reduced. Accordingly, the β-OH value is preferably 0.01/mm or more, particularly preferably 0.03/mm or more.

As a method of reducing the β-OH value, the following methods are given: (1) a method involving selecting raw materials having low water contents; (2) a method involving adding a component (such as Cl or SO₃) that reduces the β-OH value to the glass; (3) a method involving reducing the amount of water in a furnace atmosphere; (4) a method involving performing N₂ bubbling in molten glass; (5) a method involving adopting a small melting furnace; (6) a method involving increasing the flow rate of molten glass; and (7) a method involving adopting an electric melting method.

Herein, the “β-OH value” refers to a value determined with the following mathematical formula 1 by measuring the transmittances of the glass with a FT-IR.

$$β - OH value = ( 1 / X ) log ( {T}_{1} / {T}_{2} ) \qquad [ Math . 1 ]$$

X: Sheet thickness (mm)
T₁: Transmittance (%) at a reference wavelength of 3,846 cm⁻¹
T₂: Minimum transmittance (t) at a wavelength around a hydroxy group absorption wavelength of 3,600 cm⁻¹

It is preferred that the alkali-free glass sheet of the present invention be formed by an overflow down-draw method. The overflow down-draw method refers to a method in which molten glass is caused to overflow from both sides of a heat-resistant trough-shaped structure, and the overflowing molten glass is subjected to down-draw downward at the lower end of the trough-shaped structure while being joined, to thereby manufacture the glass sheet. By the overflow down-draw method, surfaces that are to serve as the surfaces of the glass sheet are formed in a state of free surfaces without being brought into contact with the trough-shaped refractory. As a result, a glass sheet having a fire-polished surface satisfactory in surface quality can be manufactured without polishing at low cost, and a reduction in thickness is easily achieved as well.

The alkali-free glass sheet of the present invention is also preferably formed by a float method. With this method, a large glass sheet can be manufactured at low cost.

When the alkali-free glass sheet of the present invention is used for an information recording medium, the surface thereof is preferably a polished surface. When the glass surface is polished, a total thickness variation TTV can be reduced. As a result, a magnetic film can be appropriately formed, and hence the alkali-free glass sheet is suitable as a substrate for a magnetic recording medium. Meanwhile, when the alkali-free glass sheet is used for an OLED device, the surface thereof is preferably a fire-polished surface (unpolished surface) formed by an overflow down-draw method.

The sheet thickness of the alkali-free glass sheet of the present invention is not particularly limited, but is preferably 0.7 mm or less, more preferably less than 0.7 mm, still more preferably 0.6 mm or less, still more preferably less than 0.6 mm, particularly preferably 0.5 mm or less when the alkali-free glass sheet is used for an OLED device. As the sheet thickness becomes smaller, the weight of an OLED device can be reduced more. However, when the sheet thickness is too small, the strength is reduced and the sheet has excessive flexibility, and hence the sheet thickness is preferably 0.05 mm or more. The sheet thickness may be adjusted based on, for example, a flow rate and a sheet-drawing speed at the time of glass manufacture. Meanwhile, when the alkali-free glass sheet is used for a magnetic recording medium, the sheet thickness is preferably 1.5 mm or less, more preferably 1.2 mm or less, still more preferably 1.0 mm or less, particularly preferably 0.9 mm or less. When the sheet thickness is too large, the sheet needs to be etched to have a desired sheet thickness, and hence processing cost may rise. In addition, when the sheet thickness is too small, fluttering may occur, and hence the sheet thickness is preferably 0.2 mm or more, particularly preferably 0.3 mm or more.

In the alkali-free glass sheet of the present invention, when the alkali-free glass sheet is used for an OLED device, an average surface roughness Ra of the surface is preferably 1.0 nm or less, more preferably 0.5 nm or less, particularly preferably 0.2 nm or less. When the average surface roughness Ra of the surface is large, it becomes difficult to perform accurate patterning on, for example, an electrode in the manufacturing process for a display. As a result, the probability of the disconnection of a circuit electrode or the short circuit thereof is increased, and it becomes difficult to secure the reliability of the display or the like. Herein, the “average surface roughness Ra of the surface” refers to an average surface roughness Ra of a main surface (both surfaces) excluding an end surface, and may be measured with, for example, an atomic force microscope (AFM).

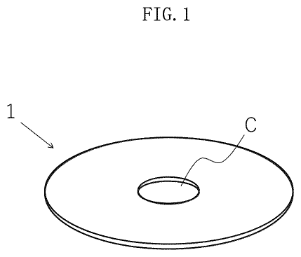

In addition, when the alkali-free glass sheet of the present invention is used as a substrate of an OLED TV display panel or a carrier for manufacturing an OLED display panel, the shape is preferably a rectangular shape. In addition, the alkali-free glass sheet of the present invention is preferably used for an information recording medium, particularly preferably used as a substrate for an energy-assisted magnetic recording medium. In order to achieve the increase in Ku by increasing the degree of ordering (ordering degree) of the magnetic layer, at the time of the formation of the magnetic layer on the substrate or before and after the formation, a base material including a glass substrate is subjected to heat treatment at a high temperature of about 800° C. In addition, the alkali-glass sheet can withstand an impact on the substrate along with high rotation of the magnetic recording medium. When the alkali-free glass sheet of the present invention is subjected to processing such as cutting, the alkali-free glass sheet is processed into a disc substrate 1 as illustrated in FIG. 1. When the alkali-free glass sheet is used as a glass substrate for a magnetic recording medium as described above, the disc substrate 1 preferably has a disc shape, and an opening C having a circular shape is still more preferably formed at a center portion.

### EXAMPLES

The present invention is described below by way of Examples. Examples below are merely examples. The present invention is by no means limited to Examples below.

Examples (Samples Nos. 1 to 35) and Comparative Example (Sample No. 36) of the present invention are shown in Tables 1 to 4.

TABLE 1

| | | No. 1 | No. 2 | No. 3 | No. 4 | No. 5 |
|---|---|---|---|---|---|---|
| Glass composition | SiO₂ | 69.15 | 69.10 | 69.13 | 69.13 | 69.00 |
| (mol %) | Al₂O₃ | 13.03 | 12.99 | 13.04 | 13.02 | 13.03 |
| | B₂O₃ | 3.20 | 3.31 | 3.20 | 3.23 | 3.34 |
| | Li₂O | 0.000 | 0.000 | 0.000 | 0.000 | 0.000 |
| | Na₂O | 0.019 | 0.014 | 0.013 | 0.012 | 0.016 |
| | K₂O | 0.006 | 0.003 | 0.002 | 0.002 | 0.001 |
| | MgO | 6.04 | 6.02 | 5.54 | 5.54 | 5.52 |
| | CaO | 6.95 | 6.46 | 7.46 | 6.97 | 6.48 |
| | SrO | 1.02 | 1.02 | 1.02 | 1.02 | 1.01 |
| | BaO | 0.50 | 0.99 | 0.50 | 0.99 | 1.49 |
| | SnO₂ | 0.08 | 0.08 | 0.08 | 0.08 | 0.08 |
| | Fe₂O₃ | 0.005 | 0.005 | 0.005 | 0.005 | 0.005 |
| | TiO₂ | 0.009 | 0.007 | 0.007 | 0.007 | 0.007 |
| | ZrO₂ | 0.003 | 0.001 | 0.001 | 0.001 | 0.001 |
| | MoO₃ | 0.0001 | 0.0002 | 0.0003 | 0.0004 | 0.0001 |
| Li₂O + Na₂O + K₂O | | 0.025 | 0.017 | 0.015 | 0.014 | 0.017 |
| MgO + CaO + SrO + BaO | | 14.5 | 14.5 | 14.5 | 14.5 | 14.5 |
| SiO₂/Al₂O₃ | | 5.31 | 5.32 | 5.30 | 5.31 | 5.29 |
| B₂O₃/Al₂O₃ | | 0.25 | 0.26 | 0.25 | 0.25 | 0.26 |
| MgO/CaO | | 0.87 | 0.93 | 0.74 | 0.79 | 0.85 |
| SrO/CaO | | 0.15 | 0.16 | 0.14 | 0.15 | 0.16 |
| BaO/CaO | | 0.07 | 0.15 | 0.07 | 0.14 | 0.23 |
| (MgO + CaO + SrO + BaO − Al₂O₃)/B₂O₃ | | 0.46 | 0.45 | 0.46 | 0.47 | 0.44 |
| 0.116 × [Al₂O₃] − | | 4.81 | 4.83 | 4.89 | 4.92 | 4.96 |
| 0.079 × [B₂O₃] + 0.155 × [MgO] + 0.299 × | | | | | | |
| [CaO] + 0.336 × [SrO] + 0.385 × [BaO] | | | | | | |
| CTE [×10⁻⁷/° C.] | | 34.2 | 34.4 | 34.6 | 34.8 | 35.1 |
| ρ [g/cm³] | | 2.49 | 2.50 | 2.49 | 2.50 | 2.52 |
| E [GPa] | | 83 | 83 | 83 | 83 | 82 |
| E/ρ [GPa/g · cm⁻³] | | 33.5 | 33.1 | 33.3 | 33.0 | 32.6 |
| Ps [° C.] | | 729 | 729 | 731 | 729 | 729 |
| Ta [° C.] | | 786 | 786 | 788 | 786 | 787 |
| Ts [° C.] | | 1,017 | 1,018 | 1,018 | 1,018 | 1,019 |
| 10⁴ dPa · s [° C.] | | 1,330 | 1,332 | 1,328 | 1,331 | 1,334 |
| 10³ dPa · s [° C.] | | 1,489 | 1,491 | 1,487 | 1,490 | 1,494 |
| 10^{2.5} dPa · s [° C.] | | 1,589 | 1,592 | 1,586 | 1,590 | 1,594 |
| TL [ ° C.] | | 1,229 | 1,214 | 1,228 | 1,223 | 1,215 |
| Log₁₀ηTL | | 4.9 | 5.0 | 4.9 | 4.9 | 5.1 |
| BHF etching amount [μm] | | 3.6 | 3.7 | 3.7 | 3.8 | 3.8 |
| | | No. 6 | No. 7 | No. 8 | No. 9 | No. 10 |
| Glass composition | SiO₂ | 69.09 | 69.13 | 69.07 | 68.92 | 69.03 |
| (mol %) | Al₂O₃ | 12.99 | 13.02 | 13.04 | 13.04 | 13.01 |
| | B₂O₃ | 3.30 | 3.23 | 3.25 | 3.42 | 3.35 |
| | Li₂O | 0.000 | 0.000 | 0.000 | 0.000 | 0.000 |
| | Na₂O | 0.013 | 0.012 | 0.011 | 0.011 | 0.011 |
| | K₂O | 0.002 | 0.001 | 0.001 | 0.001 | 0.001 |
| | MgO | 5.03 | 5.03 | 5.03 | 4.53 | 4.52 |
| | CaO | 7.98 | 7.49 | 7.00 | 7.97 | 7.47 |
| | SrO | 1.02 | 1.02 | 1.01 | 1.01 | 1.02 |
| | BaO | 0.49 | 0.99 | 1.50 | 1.00 | 1.50 |
| | SnO₂ | 0.08 | 0.07 | 0.08 | 0.08 | 0.08 |
| | Fe₂O₃ | 0.005 | 0.005 | 0.005 | 0.005 | 0.005 |
| | TiO₂ | 0.007 | 0.007 | 0.007 | 0.007 | 0.007 |
| | ZrO₂ | 0.001 | 0.001 | 0.001 | 0.001 | 0.001 |
| | MoO₃ | 0.0002 | 0.0004 | 0.0001 | 0.0002 | 0.0001 |

| | | | | | |
|---|---|---|---|---|---|
| Li₂O + Na₂O + K₂O | 0.015 | 0.013 | 0.012 | 0.012 | 0.012 |
| MgO + CaO + SrO + BaO | 14.5 | 14.5 | 14.5 | 14.5 | 14.5 |
| SiO₂/Al₂O₃ | 5.32 | 5.31 | 5.29 | 5.29 | 5.30 |
| B₂O₃/Al₂O₃ | 0.25 | 0.25 | 0.25 | 0.26 | 0.26 |
| MgO/CaO | 0.63 | 0.67 | 0.72 | 0.57 | 0.60 |
| SrO/CaO | 0.13 | 0.14 | 0.14 | 0.13 | 0.14 |
| BaO/CaO | 0.06 | 0.13 | 0.21 | 0.12 | 0.20 |
| (MgO + CaO + SrO + BaO − Al₂O₃)/B₂O₃ | 0.46 | 0.47 | 0.46 | 0.43 | 0.44 |
| 0.116 × [Al₂O₃] − | 4.94 | 5.00 | 5.05 | 5.05 | 5.10 |
| 0.079 × [B₂O₃] + 0.155 × [MgO] + 0.299 × | | | | | |
| [CaO] + 0.336 × [SrO] + 0.385 × [BaO] | | | | | |
| CTE [×10⁻⁷/° C.] | 34.9 | 35.1 | 35.3 | 35.0 | 35.5 |
| ρ [g/cm³] | 2.49 | 2.50 | 2.52 | 2.51 | 2.52 |
| E [GPa] | 83 | 82 | 82 | 82 | 82 |
| E/ρ [GPa/g · cm⁻³] | 33.2 | 32.9 | 32.6 | 32.8 | 32.5 |
| Ps [° C.] | 734 | 731 | 730 | 731 | 731 |
| Ta [° C.] | 791 | 789 | 788 | 789 | 789 |
| Ts [° C.] | 1,019 | 1,019 | 1,019 | 1,019 | 1,021 |
| 10⁴ dPa · s [° C.] | 1,331 | 1,333 | 1,336 | 1,333 | 1,335 |
| 10³ dPa · s [° C.] | 1,490 | 1,492 | 1,495 | 1,492 | 1,495 |
| 10^{2.5} dPa · s [° C.] | 1,590 | 1,592 | 1,595 | 1,592 | 1,596 |
| TL [ ° C.] | 1,208 | 1,213 | 1,200 | 1,201 | 1,178 |
| Log₁₀ηTL | 5.1 | 5.1 | 5.2 | 5.2 | 5.5 |
| BHF etching amount [μm] | 3.7 | 3.8 | 3.9 | 3.8 | 3.8 |

TABLE 2

| | | No. 11 | No. 12 | No. 13 | No. 14 | No. 15 |
|---|---|---|---|---|---|---|
| Glass composition | SiO₂ | 68.54 | 68.62 | 68.55 | 68.50 | 68.54 |
| (mol %) | Al₂O₃ | 13.05 | 13.03 | 13.01 | 13.04 | 13.01 |
| | B₂O₃ | 3.30 | 3.23 | 3.30 | 3.33 | 3.35 |
| | Li₂O | 0.000 | 0.000 | 0.000 | 0.000 | 0.000 |
| | Na₂O | 0.012 | 0.012 | 0.013 | 0.011 | 0.012 |
| | K₂O | 0.001 | 0.001 | 0.001 | 0.001 | 0.001 |
| | MgO | 6.04 | 6.03 | 5.54 | 5.53 | 5.51 |
| | CaO | 6.97 | 6.48 | 7.47 | 6.97 | 6.49 |
| | SrO | 1.52 | 1.52 | 1.52 | 1.52 | 1.51 |
| | BaO | 0.49 | 0.99 | 0.49 | 0.99 | 1.49 |
| | SnO₂ | 0.07 | 0.07 | 0.08 | 0.08 | 0.08 |
| | Fe₂O₃ | 0.005 | 0.005 | 0.006 | 0.005 | 0.005 |
| | TiO₂ | 0.006 | 0.007 | 0.007 | 0.007 | 0.007 |
| | ZrO₂ | 0.001 | 0.001 | 0.001 | 0.001 | 0.001 |
| | MoO₃ | 0.0003 | 0.0004 | 0.0001 | 0.0002 | 0.0004 |
| Li₂O + Na₂O + K₂O | | 0.013 | 0.013 | 0.014 | 0.012 | 0.013 |
| MgO + CaO + SrO + BaO | | 15.0 | 15.0 | 15.0 | 15.0 | 15.0 |
| SiO₂/Al₂O₃ | | 5.25 | 5.27 | 5.27 | 5.25 | 5.27 |
| B₂O₃/Al₂O₃ | | 0.25 | 0.25 | 0.25 | 0.26 | 0.26 |
| MgO/CaO | | 0.87 | 0.93 | 0.74 | 0.79 | 0.85 |
| SrO/CaO | | 0.22 | 0.23 | 0.20 | 0.22 | 0.23 |
| BaO/CaO | | 0.07 | 0.15 | 0.07 | 0.14 | 0.23 |
| (MgO + CaO + SrO + BaO − Al₂O₃)/B₂O₃ | | 0.59 | 0.62 | 0.61 | 0.59 | 0.59 |
| 0.116 × [Al₂O₃] − | | 4.97 | 5.02 | 5.04 | 5.09 | 5.12 |
| 0.079 × [B₂O₃] + 0.155 × [MgO] + 0.299 × | | | | | | |
| [CaO] + 0.336 × [SrO] + 0.385 × [BaO] | | | | | | |
| CTE [×10⁻⁷/° C.] | | 34.8 | 35.3 | 35.5 | 35.7 | 35.8 |
| ρ [g/cm³] | | 2.50 | 2.51 | 2.50 | 2.52 | 2.53 |
| E [GPa] | | 83 | 83 | 83 | 83 | 82 |
| E/ρ [GPa/g · cm⁻³] | | 33.3 | 33.0 | 33.1 | 32.8 | 32.5 |
| Ps [° C.] | | 728 | 728 | 729 | 728 | 727 |
| Ta [° C.] | | 785 | 785 | 786 | 785 | 785 |
| Ts [° C.] | | 1,012 | 1,013 | 1,013 | 1,014 | 1,015 |
| 10⁴ dPa · s [° C.] | | 1,323 | 1,326 | 1,323 | 1,326 | 1,327 |
| 10³ dPa · s [° C.] | | 1,478 | 1,482 | 1,478 | 1,483 | 1,485 |
| 10^{2.5} dPa · s [° C.] | | 1,576 | 1,580 | 1,577 | 1,581 | 1,583 |
| TL [ ° C.] | | 1,215 | 1,217 | 1,209 | 1,198 | 1,196 |
| Log₁₀ηTL | | 5.0 | 5.0 | 5.0 | 5.2 | 5.2 |
| BHF etching amount [μm] | | 3.8 | 3.8 | 3.8 | 3.9 | 3.9 |
| | | No. 16 | No. 17 | No. 18 | No. 19 | No. 20 |
| Glass composition | SiO₂ | 68.61 | 68.42 | 68.58 | 68.39 | 68.44 |
| (mol %) | Al₂O₃ | 13.05 | 13.07 | 13.03 | 13.02 | 13.05 |
| | B₂O₃ | 3.22 | 3.33 | 3.36 | 3.43 | 3.36 |
| | Li₂O | 0.000 | 0.000 | 0.000 | 0.000 | 0.000 |
| | Na₂O | 0.012 | 0.012 | 0.012 | 0.011 | 0.011 |
| | K₂O | 0.001 | 0.001 | 0.001 | 0.001 | 0.001 |
| | MgO | 5.03 | 5.03 | 5.00 | 4.53 | 4.51 |
| | CaO | 7.97 | 7.51 | 6.91 | 8.00 | 7.51 |
| | SrO | 1.53 | 1.52 | 1.51 | 1.52 | 1.52 |
| | BaO | 0.49 | 0.99 | 1.49 | 0.99 | 1.49 |
| | SnO₂ | 0.07 | 0.08 | 0.08 | 0.08 | 0.08 |
| | Fe₂O₃ | 0.006 | 0.006 | 0.005 | 0.006 | 0.005 |
| | TiO₂ | 0.006 | 0.007 | 0.008 | 0.007 | 0.007 |
| | ZrO₂ | 0.001 | 0.001 | 0.001 | 0.001 | 0.001 |
| | MoO₃ | 0.0002 | 0.0001 | 0.0004 | 0.0001 | 0.0002 |

| | | | | | |
|---|---|---|---|---|---|
| Li₂O + Na₂O + K₂O | 0.013 | 0.013 | 0.013 | 0.012 | 0.012 |
| MgO + CaO + SrO + BaO | 15.0 | 15.1 | 14.9 | 15.0 | 15.0 |
| SiO₂/Al₂O₃ | 5.26 | 5.23 | 5.26 | 5.25 | 5.24 |
| B₂O₃/Al₂O₃ | 0.25 | 0.26 | 0.26 | 0.26 | 0.26 |
| MgO/CaO | 0.63 | 0.67 | 0.72 | 0.57 | 0.60 |
| SrO/CaO | 0.19 | 0.20 | 0.22 | 0.19 | 0.20 |
| BaO/CaO | 0.06 | 0.13 | 0.22 | 0.12 | 0.20 |
| (MgO + CaO + SrO + BaO − Al₂O₃)/B₂O₃ | 0.62 | 0.60 | 0.56 | 0.59 | 0.59 |
| 0.116 × [Al₂O₃] − | 5.13 | 5.17 | 5.17 | 5.23 | 5.28 |
| 0.079 × [B₂O₃] + 0.155 × [MgO] + 0.299 × | | | | | |
| [CaO] + 0.336 × [SrO] + 0.385 × [BaO] | | | | | |
| CTE [×10⁻⁷/° C.] | 35.8 | 36.0 | 36.1 | 36.5 | 36.6 |
| ρ [g/cm³] | 2.50 | 2.52 | 2.53 | 2.52 | 2.53 |
| E [GPa] | 83 | 82 | 82 | 82 | 82 |
| E/ρ [GPa/g · cm⁻³] | 33.0 | 32.7 | 32.4 | 32.6 | 32.2 |
| Ps [° C.] | 729 | 728 | 727 | 728 | 727 |
| Ta [° C.] | 786 | 786 | 785 | 786 | 784 |
| Ts [° C.] | 1,014 | 1,015 | 1,015 | 1,015 | 1,015 |
| 10⁴ dPa · s [° C.] | 1,323 | 1,326 | 1,329 | 1,326 | 1,328 |
| 10³ dPa · s [° C.] | 1,480 | 1,481 | 1,486 | 1,482 | 1,484 |
| 10^{2.5} dPa · s [° C.] | 1,578 | 1,579 | 1,585 | 1,580 | 1,581 |
| TL [ ° C.] | 1,221 | 1,192 | 1,172 | 1,212 | 1,203 |
| Log₁₀ηTL | 4.9 | 5.2 | 5.5 | 5.0 | 5.1 |
| BHF etching amount [μm] | 3.9 | 3.9 | 3.9 | 3.9 | 4.0 |

TABLE 3

| | | No. 21 | No. 22 | No. 23 | No. 24 | No. 25 |
|---|---|---|---|---|---|---|
| Glass composition | SiO₂ | 68.75 | 68.70 | 68.77 | 68.68 | 68.68 |
| (mol %) | Al₂O₃ | 12.99 | 12.98 | 13.00 | 12.97 | 12.99 |
| | B₂O₃ | 3.77 | 3.78 | 3.66 | 3.78 | 3.81 |
| | Li₂O | 0.000 | 0.000 | 0.000 | 0.000 | 0.000 |
| | Na₂O | 0.018 | 0.017 | 0.020 | 0.038 | 0.015 |
| | K₂O | 0.003 | 0.003 | 0.003 | 0.003 | 0.002 |
| | MgO | 4.51 | 4.77 | 5.02 | 5.01 | 5.01 |
| | CaO | 8.37 | 7.89 | 7.90 | 7.42 | 6.90 |
| | SrO | 1.02 | 1.02 | 1.52 | 1.52 | 1.51 |
| | BaO | 0.49 | 0.74 | 0.01 | 0.49 | 0.98 |
| | SnO₂ | 0.08 | 0.08 | 0.08 | 0.08 | 0.08 |
| | Fe₂O₃ | 0.006 | 0.006 | 0.006 | 0.006 | 0.006 |
| | TiO₂ | 0.008 | 0.009 | 0.020 | 0.008 | 0.008 |
| | ZrO₂ | 0.001 | 0.001 | 0.001 | 0.001 | 0.001 |
| | MoO₃ | 0.0001 | 0.0002 | 0.0004 | 0.0002 | 0.0001 |
| Li₂O + Na₂O + K₂O | | 0.021 | 0.020 | 0.023 | 0.041 | 0.017 |
| MgO + CaO + SrO + BaO | | 14.4 | 14.4 | 14.5 | 14.4 | 14.4 |
| SiO₂/Al₂O₃ | | 5.29 | 5.29 | 5.29 | 5.29 | 5.29 |
| B₂O₃/Al₂O₃ | | 0.29 | 0.29 | 0.28 | 0.29 | 0.29 |
| MgO/CaO | | 0.54 | 0.60 | 0.64 | 0.68 | 0.73 |
| SrO/CaO | | 0.12 | 0.13 | 0.19 | 0.20 | 0.22 |
| BaO/CaO | | 0.06 | 0.09 | 0.00 | 0.07 | 0.14 |
| (MgO + CaO + SrO + BaO − Al₂O₃)/B₂O₃ | | 0.37 | 0.38 | 0.40 | 0.39 | 0.37 |
| 0.116 × [Al₂O₃] − | | 4.94 | 4.93 | 4.87 | 4.90 | 4.93 |
| 0.079 × [B₂O₃] + 0.155 × [MgO] + 0.299 × | | | | | | |
| [CaO] + 0.336 × [SrO] + 0.385 × [BaO] | | | | | | |
| CTE [×10⁻⁷/° C.] | | 35.1 | 35.0 | 34.6 | 34.8 | 35.0 |
| ρ [g/cm³] | | 2.49 | 2.49 | 2.48 | 2.49 | 2.51 |
| E [GPa] | | 81 | 82 | 82 | 82 | 82 |
| E/ρ [GPa/g · cm⁻³] | | 32.7 | 32.9 | 33.2 | 32.9 | 32.6 |
| Ps [° C.] | | 726 | 727 | 726 | 726 | 726 |
| Ta [° C.] | | 784 | 784 | 783 | 783 | 783 |
| Ts [° C.] | | 1,014 | 1,013 | 1,014 | 1,013 | 1,015 |
| 10⁴ dPa · s [° C.] | | 1,308 | 1,323 | 1,320 | 1,318 | 1,327 |
| 10³ dPa · s [° C.] | | 1,480 | 1,482 | 1,478 | 1,477 | 1,489 |
| 10^{2.5} dPa · s [° C.] | | 1,478 | 1,582 | 1,578 | 1,576 | 1,591 |
| TL [ ° C.] | | 1,206 | 1,197 | 1,231 | 1,206 | 1,206 |
| Log₁₀ηTL | | 4.9 | 5.1 | 4.8 | 5.0 | 5.1 |
| BHF etching amount [μm] | | 3.6 | 3.6 | 3.6 | 3.6 | 3.6 |
| | | No. 26 | No. 27 | No. 28 | No. 29 | No. 30 |
| Glass composition | SiO₂ | 68.70 | 68.22 | 68.14 | 68.87 | 68.85 |
| (mol %) | Al₂O₃ | 12.98 | 12.97 | 13.02 | 13.03 | 13.01 |
| | B₂O₃ | 3.78 | 3.78 | 3.76 | 3.50 | 3.49 |
| | Li₂O | 0.000 | 0.000 | 0.000 | 0.000 | 0.000 |
| | Na₂O | 0.017 | 0.018 | 0.035 | 0.013 | 0.015 |
| | K₂O | 0.002 | 0.002 | 0.002 | 0.002 | 0.001 |
| | MgO | 5.01 | 6.01 | 5.52 | 4.75 | 4.51 |
| | CaO | 7.91 | 6.41 | 7.41 | 7.98 | 8.50 |
| | SrO | 0.51 | 2.00 | 2.00 | 1.02 | 1.02 |
| | BaO | 0.99 | 0.48 | 0.01 | 0.76 | 0.51 |
| | SnO₂ | 0.08 | 0.08 | 0.08 | 0.08 | 0.08 |
| | Fe₂O₃ | 0.006 | 0.006 | 0.006 | 0.006 | 0.006 |
| | TiO₂ | 0.009 | 0.008 | 0.008 | 0.007 | 0.007 |
| | ZrO₂ | 0.001 | 0.001 | 0.001 | 0.001 | 0.001 |
| | MoO₃ | 0.0004 | 0.0001 | 0.0002 | 0.0001 | 0.0002 |

| | | | | | |
|---|---|---|---|---|---|
| Li₂O + Na₂O + K₂O | 0.019 | 0.020 | 0.037 | 0.015 | 0.016 |
| MgO + CaO + SrO + BaO | 14.4 | 14.9 | 14.9 | 14.5 | 14.5 |
| SiO₂/Al₂O₃ | 5.29 | 5.26 | 5.23 | 5.28 | 5.29 |
| B₂O₃/Al₂O₃ | 0.29 | 0.29 | 0.29 | 0.27 | 0.27 |
| MgO/CaO | 0.63 | 0.94 | 0.74 | 0.60 | 0.53 |
| SrO/CaO | 0.07 | 0.31 | 0.27 | 0.13 | 0.12 |
| BaO/CaO | 0.12 | 0.08 | 0.00 | 0.09 | 0.06 |
| (MgO + CaO + SrO + BaO − Al₂O₃)/B₂O₃ | 0.38 | 0.51 | 0.51 | 0.42 | 0.44 |
| 0.116 × [Al₂O₃] − | 4.90 | 4.91 | 4.96 | 4.99 | 5.01 |
| 0.079 × [B₂O₃] + 0.155 × [MgO] + 0.299 × | | | | | |
| [CaO] + 0.336 × [SrO] + 0.385 × [BaO] | | | | | |
| CTE [×10⁻⁷/° C.] | 34.7 | 35.0 | 34.8 | 35.1 | 35.4 |
| ρ [g/cm³] | 2.49 | 2.51 | 2.49 | 2.50 | 2.49 |
| E [GPa] | 82 | 82 | 82 | 82 | 82 |
| E/ρ [GPa/g · cm⁻³] | 32.8 | 32.9 | 33.0 | 32.8 | 32.9 |
| Ps [° C.] | 726 | 723 | 724 | 730 | 731 |
| Ta [° C.] | 783 | 780 | 780 | 787 | 788 |
| Ts [° C.] | 1,013 | 1,009 | 1,008 | 1,018 | 1,017 |
| 10⁴ dPa · s [° C.] | 1,324 | 1,316 | 1,312 | 1,327 | 1,325 |
| 10³ dPa · s [° C.] | 1,483 | 1,472 | 1,469 | 1,486 | 1,483 |
| 10^{2.5} dPa · s [° C.] | 1,585 | 1,571 | 1,568 | 1,585 | 1,583 |
| TL [ ° C.] | 1,225 | 1,204 | 1,209 | 1,202 | 1,224 |
| Log₁₀ηTL | 4.9 | 5.0 | 4.9 | 5.1 | 4.9 |
| BHF etching amount [μm] | 3.6 | 3.7 | 3.7 | 3.8 | 3.7 |

TABLE 4

| | | No. 31 | No. 32 | No. 33 | No. 34 | No. 35 | No. 36 |
|---|---|---|---|---|---|---|---|
| Glass composition | SiO₂ | 68.29 | 68.32 | 68.75 | 68.51 | 68.09 | 70.02 |
| (mol %) | Al₂O₃ | 13.54 | 13.51 | 13.03 | 12.79 | 13.01 | 12.54 |
| | B₂O₃ | 3.50 | 3.49 | 3.57 | 3.58 | 3.77 | 0.67 |
| | Li₂O | 0.000 | 0.000 | 0.000 | 0.000 | 0.000 | 0.000 |
| | Na₂O | 0.013 | 0.014 | 0.014 | 0.012 | 0.014 | 0.010 |
| | K₂O | 0.001 | 0.001 | 0.002 | 0.002 | 0.002 | 0.001 |
| | MgO | 5.01 | 5.01 | 5.02 | 6.02 | 6.01 | 5.71 |
| | CaO | 8.02 | 8.54 | 8.24 | 6.73 | 6.74 | 4.60 |
| | SrO | 1.02 | 0.52 | 0.51 | 1.76 | 1.76 | 2.17 |
| | BaO | 0.51 | 0.51 | 0.76 | 0.50 | 0.51 | 4.02 |
| | SnO₂ | 0.08 | 0.08 | 0.08 | 0.08 | 0.08 | 0.10 |
| | Fe₂O₃ | 0.006 | 0.006 | 0.006 | 0.006 | 0.006 | 0.004 |
| | TiO₂ | 0.007 | 0.007 | 0.007 | 0.007 | 0.007 | 0.005 |
| | ZrO₂ | 0.001 | 0.001 | 0.001 | 0.001 | 0.001 | 0.012 |
| | MoO₃ | 0.0004 | 0.0002 | 0.0003 | 0.0001 | 0.0001 | 0.0002 |

| | | | | | | |
|---|---|---|---|---|---|---|
| Li₂O + Na₂O + K₂O | 0.014 | 0.015 | 0.016 | 0.014 | 0.016 | 0.011 |
| MgO + CaO + SrO + BaO | 14.6 | 14.6 | 14.5 | 15.0 | 15.0 | 16.5 |
| SiO₂/Al₂O₃ | 5.04 | 5.06 | 5.27 | 5.36 | 5.23 | 5.58 |
| B₂O₃/Al₂O₃ | 0.26 | 0.26 | 0.27 | 0.28 | 0.29 | 0.05 |
| MgO/CaO | 0.62 | 0.59 | 0.61 | 0.89 | 0.89 | 1.24 |
| SrO/CaO | 0.13 | 0.06 | 0.06 | 0.26 | 0.26 | 0.47 |
| BaO/CaO | 0.06 | 0.06 | 0.09 | 0.07 | 0.07 | 0.87 |
| (MgO + CaO + SrO + BaO − Al₂O₃)/B₂O₃ | 0.29 | 0.31 | 0.42 | 0.62 | 0.53 | 5.89 |
| 0.116 × [Al₂O₃] − | 5.01 | 4.99 | 4.93 | 4.93 | 4.95 | 5.94 |
| 0.079 × [B₂O₃] + 0.155 × [MgO] + 0.299 × | | | | | | |
| [CaO] + 0.336 × [SrO] + 0.385 × [BaO] | | | | | | |
| CTE [×10⁻⁷/° C.] | 34.9 | 34.7 | 34.9 | 35.2 | 35.3 | 39.3 |
| ρ [g/cm³] | 2.50 | 2.49 | 2.49 | 2.50 | 2.50 | 2.64 |
| E [GPa] | 83 | 83 | 82 | 82 | 82 | 83 |
| E/ρ [GPa/g · cm⁻³] | 33.1 | 33.3 | 33.0 | 32.9 | 32.9 | 31.4 |
| Ps [° C.] | 733 | 734 | 730 | 725 | 725 | 750 |
| Ta [° C.] | 789 | 790 | 787 | 782 | 782 | 809 |
| Ts [° C.] | 1,016 | 1,016 | 1,017 | 1,011 | 1,009 | 1,044 |
| 10⁴ dPa · s [° C.] | 1,322 | 1,320 | 1,325 | 1,320 | 1,315 | 1,364 |
| 10³ dPa · s [° C.] | 1,480 | 1,475 | 1,488 | 1,478 | 1,473 | 1,528 |
| 10^{2.5} dPa · s [° C.] | 1,579 | 1,573 | 1,589 | 1,579 | 1,575 | 1,632 |
| TL [ ° C.] | 1,217 | 1,224 | 1,219 | 1,232 | 1,204 | 1,220 |
| Log₁₀ηTL | 4.9 | 4.9 | 4.9 | 4.8 | 5.0 | 5.2 |
| BHF etching amount [μm] | 3.8 | 3.8 | 3.8 | 3.7 | 3.7 | 6.8 |

First, a glass batch prepared by blending glass raw materials so as to achieve each of the glass compositions shown in the tables was loaded into a platinum crucible, and melted at from 1,600° C. to 1,680° C. for 24 hours. In the melting of the glass batch, molten glass was stirred to be homogenized with a platinum stirrer. Next, the molten glass was poured onto a carbon sheet, formed into a sheet shape, and then annealed at a temperature around an annealing point for 30 minutes. Each of the resultant samples was evaluated for its average thermal expansion coefficient CTE within a temperature range of from 30° C. to 380° C., density ρ, Young's modulus E, specific Young's modulus E/ρ, strain point Ps, annealing point Ta, softening point Ts, temperature at a viscosity at high temperature of 10⁴ dPa·s, temperature at a viscosity at high temperature of 10³ dPa·s, temperature at a viscosity at high temperature of 10^{2.5} dPa·s, liquidus temperature TL, viscosity log₁₀ηTL at the liquidus temperature TL, and BHF etching amount serving as an indicator of durability to BHF.

The average thermal expansion coefficient CTE within a temperature range of from 30° C. to 380° C. is a value measured with a dilatometer.

The density ρ is a value measured by a well-known Archimedes method.

The Young's modulus E refers to a value measured by a well-known resonance method.

The specific Young's modulus E/ρ is a value obtained by dividing the Young's modulus by the density.

The strain point Ps, the annealing point Ta, and the softening point Ts are values measured based on methods specified in ASTM C336 and C338.

The temperatures at viscosities at high temperature of 10⁴ dPa·s, 10³ dPa·s, and 10^{2.5} dPa·s are values measured by a platinum sphere pull up method.

The liquidus temperature TL is a temperature at which a crystal precipitates after glass powder that has passed through a standard 30-mesh sieve (500 μm) and remains on a 50-mesh sieve (300 μm) is placed in a platinum boat and kept for 24 hours in a gradient heating furnace.

The liquidus viscosity log₁₀ηTL is a value obtained by measuring the viscosity of the glass at the liquidus temperature TL by a platinum sphere pull up method.

The BHF etching amount is a value obtained as follows: both surfaces of the sample are subjected to optical polishing; part of the sample surface is subjected to masking; the resultant is immersed in a 63BHF (HF: 6 mass %, NH₄F: 30 mass %) solution at room temperature for 30 minutes; and then a step between the masking portion and etching portion of the surface of the sample thus obtained is measured with Surfcorder ET4000 (manufactured by Kosaka Laboratory Ltd.).

As apparent from the tables, each of Samples Nos. 1 to 35, in which the glass composition is restricted to a predetermined range, has a Young's modulus of 81 GPa or more, a strain point of 723° C. or more, a liquidus temperature of 1,232° C. or less, a liquidus viscosity of 10^{3.6} dPa·s or more, and a BHF etching amount of 4.0 μm or less. Accordingly, each of Samples Nos. 1 to 35 is excellent in productivity, and has high durability to BHF, and a sufficiently high strain point and a sufficiently high Young's modulus, and is hence suitable as a substrate for an OLED device.

Meanwhile, Sample No. 36 had a BHF etching amount as large as 6.8 μm, and hence had low durability to BHF.

### INDUSTRIAL APPLICABILITY

The alkali-free glass sheet of the present invention is suitable as a substrate for a display panel for an OLED device, particularly for an OLED TV, or as a carrier for manufacturing an OLED display panel. Besides, the alkali-free glass sheet of the present invention is also suitable, for example, as a substrate for a display such as a liquid crystal display, a cover glass for an image sensor, such as a charge coupled device (CCD) or a contact image sensor (CIS), a substrate and a cover glass for a solar cell, or a substrate for an OLED lighting device.

In addition, the alkali-free glass sheet of the present invention has a sufficiently high strain point and a sufficiently high Young's modulus, and is hence also suitable as a glass substrate for a magnetic recording medium. When the strain point is high, deformation of the glass sheet is less liable to occur even when heat treatment at high temperature such as heat assistance or laser irradiation is performed. As a result, when an increase in Ku is to be achieved, a higher heat treatment temperature can be adopted, and hence a magnetic recording apparatus having a large recording density is easily produced. In addition, when the Young's modulus is high, deflection or vibration (fluttering) of the glass substrate is less liable to occur at the time of high-speed rotation, and hence collision between an information recording medium and a magnetic head can be prevented.

### REFERENCE SIGNS LIST

1 disc substrate (glass substrate for magnetic recording medium)

1. An alkali-free glass sheet, comprising as a glass composition, in terms of mol %, 65% to 72% of SiO₂, 11% to 15% of Al₂O₃, 2% to 5% of B₂O₃, 0% to 0.5% of Li₂O+Na₂O+K₂O, 2% to 8% of MgO, 4% to 10% of CaO, 0% to 4% of SrO, 0% to 4% of BaO, and 11% to 17% of MgO+CaO+SrO+BaO, and having a mole percent ratio (MgO+CaO+SrO+BaO−Al₂O₃)/B₂O₃ of from 0.2 to 1, a mole percent ratio SrO/CaO of from 0 to 0.6, a mole percent ratio BaO/CaO of from 0 to 0.6, and a value determined from the formula 0.116×[Al₂O₃]×0.079×[B₂O₃]+0.155×[MgO]+0.299×[CaO]+0.336×[SrO]+0.385×[BaO] of from 2% to 8%.

2. The alkali-free glass sheet according to claim 1, wherein the alkali-free glass sheet comprises, as the glass composition, in terms of mol %, 66% to 71% of SiO₂, 12% to 14% of Al₂O₃, 2.5% to 4% of B₂O₃, 0% to 0.1% of Li₂O+Na₂O+K₂O, 3% to 7% of MgO, 5% to 9% of CaO, 0.1% to 3% of SrO, 0.1% to 3% of BaO, and 12% to 16% of MgO+CaO+SrO+BaO, and has a mole percent ratio (MgO+CaO+SrO+BaO−Al₂O₃)/B₂O₃ of from 0.2 to 0.65, a mole percent ratio SrO/CaO of from 0 to 0.32, a mole percent ratio BaO/CaO of from 0 to 0.25, and a value determined from the formula 0.116×[Al₂O₃]−0.079×[B₂O₃]+0.155×[MgO]+0.299×[CaO]+0.336×[SrO]+0.385×[BaO] of from 4.6% to 7%.

3. The alkali-free glass sheet according to claim 1,
wherein the alkali-free glass sheet is substantially free of As₂O₃ and Sb₂O₃ in the glass composition, and further comprises 0.001 mol % to 1 mol % of SnO₂.

4. The alkali-free glass sheet according to claim 1, wherein the alkali-free glass sheet has a Young's modulus of 81 GPa or more, a strain point of 720° C. or more, and a liquidus temperature of 1,400° C. or less.

5. The alkali-free glass sheet according to claim 1, wherein the alkali-free glass sheet has a strain point of 725° C. or more.

6. The alkali-free glass sheet according to claim 1, wherein the alkali-free glass sheet has a Young's modulus of more than 82 GPa.

7. The alkali-free glass sheet according to claim 1, wherein the alkali-free glass sheet has a specific Young's modulus of 31 GPa/g·cm⁻³ or more.

8. The alkali-free glass sheet according to claim 1, wherein the alkali-free glass sheet has an average thermal expansion coefficient within a temperature range of from 30° C. to 380° C. of from 30×10⁻⁷/° C. to 50×10⁻⁷/° C.

9. The alkali-free glass sheet according to claim 1, wherein the alkali-free glass sheet has an annealing point of 780° C. or more.

10. The alkali-free glass sheet according to claim 1, wherein the alkali-free glass sheet has a liquidus viscosity of 10^{3.9} dPa·s or more.

11. The alkali-free glass sheet according to claim 1, wherein the alkali-free glass sheet is used for an OLED device.

12. The alkali-free glass sheet according to claim 1, wherein the alkali-free glass sheet is used for an information recording medium.
